(19) United States
(12) Patent Application Publication
(10) Pub. No.: US 2021/0005598 A1
(43) Pub. Date: Jan. 7, 2021

(54) BIDIRECTIONAL ELECTROSTATIC DISCHARGE PROTECTION DEVICE

(71) Applicant: CSMC TECHNOLOGIES FAB2 CO., LTD., Jiangsu (CN)

(72) Inventor: Guangyang WANG, Jiangsu (CN)

(21) Appl. No.: 16/766,635

(22) PCT Filed: Nov. 29, 2018
(86) PCT No.: PCT/CN2018/118073

§ 371 Date: May 22, 2020

(30) Foreign Application Priority Data
Dec. 28, 2017 (CN) 201711465440.4

(51) Int. Cl. H01L 27/02

(52) U.S. Cl. CPC H01L 27/0255; H01L 27/0207

(57) ABSTRACT

Provided by the present disclosure is a bidirectional electrostatic discharge protection device which includes a first doped region, a second doped region, a third doped region, a first diode and a second diode. The first doped region has a first conductivity type, and the second doped region and the third doped region both have a second conductivity type. The first doped region has a ring structure outside the second doped region and the third doped region. A cathode of the first diode is coupled to the first doped region, and an anode of the first diode is coupled to a first port together with the second doped region. A cathode of the second diode is coupled to the first doped region, and an anode of the second diode is coupled to a second port together with the third doped region.

### TECHNICAL FIELD

The present disclosure relates to semiconductor design and manufacture, more specifically to a bidirectional electrostatic discharge protection device.

### BACKGROUND

As the manufacture of integrated circuits entering the era of deep submicron of integrated circuit linewidth and the process feature sizes of CMOS continuing to shrink, the capacity of transistors to withstand high voltages and high currents is decreasing. The deep submicron CMOS integrated circuit is particularly vulnerable to electrostatic shock and is thereby prone to fail, resulting in a low product reliability.

Electrostatic discharge (ESD) is a common phenomenon during the processes of manufacture, production, assembly, testing and transportation of integrated circuit devices or chips. Electrostatic discharge can generate a large current in a short period of time, which causes fatal damages to the integrated circuits and is therefore a critical issue that causes failure during the production and applications of integrated circuits. For example, the electrostatic discharge on human body model (HBM) usually occurs in hundreds of nanoseconds, with a maximum peak current probably being up to several amperes. Other types of electrostatic discharge may require a shorter time to occur with a larger generated current. The power consumption generated as such a large current passes through the integrated circuit in a short time will exceed the maximum allowed value, thereby causing serious physical damages to the integrated circuits and leading to its final failure.

In practical applications, this problem is solved through improvements of either the environment or the circuit itself In terms of environment, it is resolved mainly by reducing the generation of static electricity and removing static electricity in time, for example, using materials that are not easy to generate static electricity, increasing environmental humidity and grounding operators and arrangements, etc. In terms of circuit, it is mainly to increase the electrostatic discharge tolerance of the integrated circuits, such as adding additional electrostatic discharge protection devices or circuits to protect the internal circuit of the integrated circuits from being damaged by electrostatic discharge, which thereby increases the device area and is not conducive to the improvement of the circuit integration. In addition, the existing electrostatic discharge protection devices are uneasy to control and are prone to cause latchup, thereby leading to circuit instability. There are also some problems such as the introduction of large on-resistance and the unsatisfactory internal circuit protection.

Therefore, the structure of the existing electrostatic discharge protection devices needs to be improved.

### SUMMARY

To solve at least one of the existing problems, the present disclosure provides a bidirectional electrostatic discharge protection device, which includes:
a first doped region with a first conductivity type;
a second doped region with a second conductivity type;
a third doped region with the second conductivity type, wherein the first doped region has a ring structure outside the second doped region and the third doped region;
a first diode having a cathode coupled to the first doped region, and an anode coupled to a first port together with the second doped region; and
a second diode having a cathode coupled to the first doped region, and an anode coupled to a second port together with the third doped region.

Details of one or more embodiments of the present disclosure are set forth in the accompanying drawings and description below. Other features, objects, and advantages of the disclosure will become apparent from the description, the drawings, and the claims

### BRIEF DESCRIPTION OF THE DRAWINGS

In order to better describe and illustrate embodiments and/or examples of the inventions disclosed herein, reference may be made to one or more drawings. The additional details or examples used to describe the drawings should not be considered as limiting the scope of any of the disclosed inventions, the described embodiments and/or examples, and the best modes of these inventions as can be understood.

FIG. 1 is a schematic view of a structure of a conventional bidirectional electrostatic discharge protection device;

FIG. 2 is a schematic view of a structure of the bidirectional electrostatic discharge protection device according to an embodiment of the present disclosure;

FIG. 3A shows an equivalent circuit of a bidirectional electrostatic discharge protection device according to an embodiment of the present disclosure when a first port is coupled to a high potential and a second port is coupled to a low potential; and

FIG. 3B shows an equivalent circuit of a bidirectional electrostatic discharge protection device according to an embodiment of the present disclosure when a first port is coupled to the low potential and a second port is coupled to the high potential.

### DETAILED DESCRIPTION

In the following description, numerous specific details are given in order to provide a more thorough understanding of the present disclosure. However, it will be apparent to those skilled in the art that the present disclosure can be implemented without one or more of these details. In other examples, in order to avoid confusion with the present disclosure, some technical features known in the art are not described.

It should be understood that the present disclosure can be implemented in different forms and should not be construed as being limited to the embodiments set forth herein. Rather, these embodiments are provided so that this disclosure will be thorough and complete, and will fully unveil the scope of the disclosure to those skilled in the art. In the drawings, the sizes and relative proportions of layers and regions may be simplified for clarity. The same reference numerals denote the same elements throughout the description.

It will be understood that when an element or layer is referred to as being “on”, “adjacent to”, “connected to” or “coupled to” another element or layer, it can be directly on, adjacent to, connected to, or coupled to the other element or layer, or intervening elements or layers may be present. In contrast, when an element is referred to as being “directly on”, “directly adjacent to”, “directly connected to” or “directly coupled to” another element or layer, there is no intervening element or layer. It should be understood that although the terms first, second, third, etc. may be used to describe various elements, components, regions, layers and/or sections, these elements, components, regions, layers and/or sections should not be limited by these terms. These terms only intend to distinguish one element, component, region, layer or section from another element, component, region, layer or section. Thus, a first element, component, region, layer or section discussed below can also be described as a second element, component, region, layer or section without departing from the teachings of this disclosure.

Spatial relation terms such as “below”, “beneath”, “underneath”, “under”, “above”, “at the top of”, etc. are used herein for convenience of description to describe the relationship between one element or feature and other elements or features shown in the figures. It should be understood that the spatial relationship terms are intended to include different orientations of the devices in use and operation in addition to the orientations shown in the figures. For example, if a device in the figures is turned over, then the element or feature that described as “below” or “under” other elements or features would then be oriented “above” the other element or feature. Thus, the exemplary terms “below” and “under” can include both an above and a below orientation. The device can also be oriented (such as 90 degrees rotation or other orientations) and the spatial description used herein will be interpreted accordingly.

The terms used herein are for the purpose of describing particular embodiments only and are not intended as a limitation of the disclosure. As used herein, the singular forms “a”, “one” and “said/the” are intended to include the plural forms as well, unless the context clearly indicates otherwise. It should also be understood that the terms “composing” and/or “including”, when used in this specification, determine the presence of features, integers, steps, operations, elements and/or components, but do not exclude the presence or addition of one or more other features, integers, steps, operations, elements, parts, and/or groups. As used herein, the term “and/or” includes any and all combinations of the associated listed items.

Electrostatic discharge (ESD) is a common phenomenon that occurs during the manufacture, production, assembly, testing, and transportation of integrated circuit devices or chips. The large current that is generated in a short time during electrostatic discharge can cause fatal damages to integrated circuits, which is a critical issue that causes failure in the production and applications of integrated circuits.

Most of the conventional electrostatic discharge protection devices are of single direction protection. For example, if a protection between the power line and the ground line is desired, only a single direction ESD protection device between them is required. However, for some integrated circuits, the power supply voltages are not always constant but the value or the direction thereof may change. Consequently, the conventional ESD protection devices not only fail to meet the protection requirements of this kind of integrated circuits, but also may affect the normal operation of the integrated circuits. Therefore, a device capable of providing bidirectional electrostatic discharge protection is required to meet the design requirement.

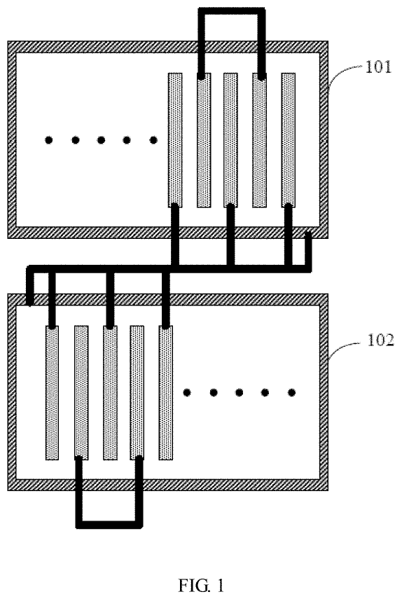

There are two conventional bidirectional electrostatic discharge protection solutions. The first one is to use a bidirectional silicon controlled rectifier (SCR). The disadvantage is that it is not easy to control and prone to cause latchup, which brings an adverse impact on the stability of the circuit. The second one is to connect a ESD device 101 and a ESD device 102 back to back in series as shown in FIG. 1. However, the on-resistance introduced by the connection in series is large, which is not good for protecting the internal circuit and takes up a large device area.

To solve at least one of the above problems, the present disclosure proposes a bidirectional electrostatic discharge protection device, which includes a first doped region, a second doped region, a third doped region, a first diode and a second diode. The first doped region has a first conductivity type, and the second doped region and the third doped region each have a second conductivity type. The first doped region has a ring structure outside the second doped region and the third doped region. A cathode of the first diode is coupled to the first doped region, and an anode of the first diode and the second doped region are coupled to a first port together. A cathode of the second diode is coupled to the first doped region, and an anode of the second diode and the third doped region are coupled to a second port together.

The first doped region, the second doped region and the third doped region jointly form one bipolar transistor, or two or more bipolar transistors coupled in parallel.

The second doped regions and the third doped regions are alternately arranged inside the first doped region.

The second doped region and the third doped region are both elongated.

The first doped region is heavily doped.

The second doped region and the third doped region are heavily doped.

When the first port is coupled to a high potential and the second port is coupled to a low potential, the first diode is turned on while the second diode is turned off, and when the first port is coupled to the low potential and the second port is coupled to the high potential, the first diode is turned off while the second diode is turned on, so that static electricity is released with bidirectional electrostatic discharge protection by controlling the bipolar transistor.

The first port is an I/O terminal and the second port is a ground terminal

The first diode, the second diode, and the bipolar transistor formed by the first doped region, the second doped region and the third doped region are disposed in different well regions from one another.

The first conductivity type is N-type and the second conductivity type is P-type.

The bidirectional electrostatic discharge protection device provided by the present disclosure has advantages of saving layout area, a low trigger voltage required, good protecting performance, a flexible structure, and providing protection under different voltages.

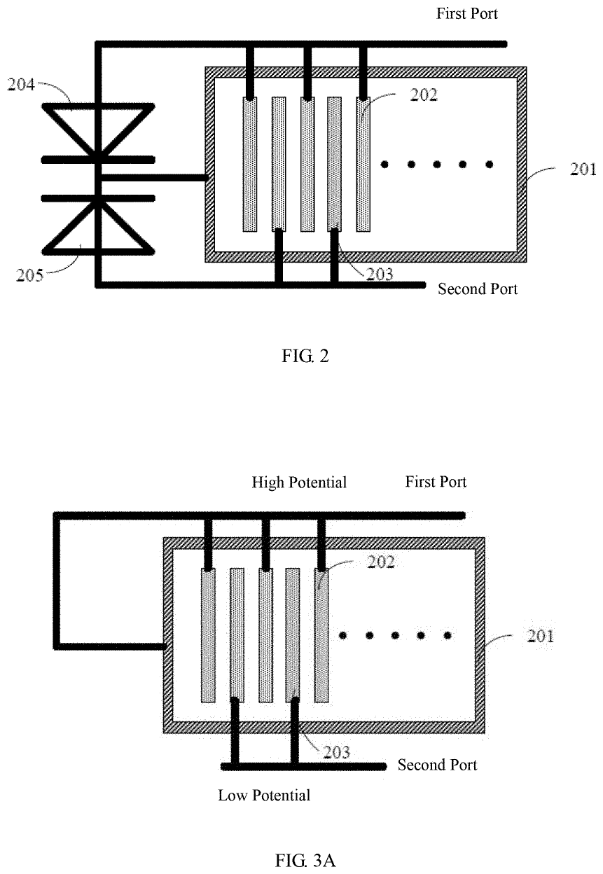

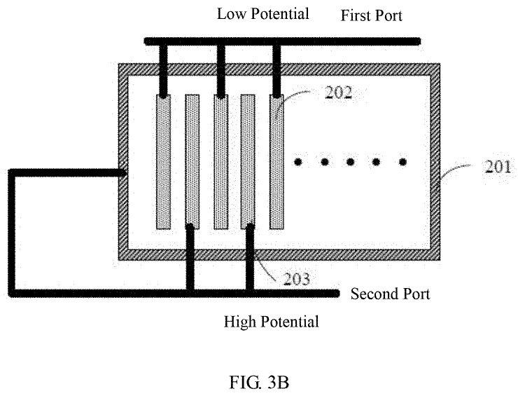

The structure of the bidirectional electrostatic discharge protection device according to an embodiment of the present disclosure will be described in detail below with reference to FIGS. 2, 3A, and 3B.

As shown in FIG. 2, a bidirectional electrostatic discharge protection device provided by an embodiment of the present disclosure includes a first doped region 201, a second doped region 202, a third doped region 203, a first diode 204 and a second diode 205. The first doped region 201 has a ring structure outside the second doped region 202 and the third doped region 203. A cathode of the first diode 204 is coupled to the first doped region 201, and an anode of the first diode 204 and the second doped region 202 are coupled to a first port together. A cathode of the second diode 205 is coupled to the first doped region 201, and an anode of the second diode 205 and the third doped region 203 are coupled to a second port together.

As an example, the first doped region 201, the second doped region 202, and the third doped region 203 are heavily doped regions. The first diode 204, the second diode 205, and a bipolar transistor formed by the first doped region 201, the second doped region 202 and the third doped region 203 are disposed in different well regions to avoid interference with one another.

In this embodiment, the first doped region 201, the second doped region 202, and the third doped region 203 jointly form a bipolar transistor, or two or more bipolar transistors coupled in parallel. The first conductivity type is N-type and the second conductivity type is P-type. The first doped region 201, the second doped region 202 and the third doped region 203 jointly form a PNP-type transistor. In other embodiments where the first conductivity type is P-type and the second conductivity type is N-type, then the first doped region 201, the second doped region 202 and the third doped region 203 jointly form an NPN-type transistor. The main dopant(s) for P-type doping is(are) one or more of trivalent dopants, such as boron. The main dopant(s) for N-type doping is(are) one or more of pentavalent dopants, such as phosphorus or arsenic. In one example, the second doped regions 202 and the third doped regions 203 are alternately arranged inside the first doped region 201. In other embodiments, the second doped regions 202 and the third doped regions 203 are both elongated and alternately arranged inside the first doped regions 201.

When the first port is coupled to a high potential and the second port is coupled to a low potential, the first diode 204 is turned on while the second diode 205 is turned off When the first port is coupled to the low potential and the second port is coupled to the high potential, the first diode 204 is turned off while the second diode 205 is turned on. Therefore, static electricity is released with bidirectional electrostatic discharge protection by controlling the bipolar transistor formed by the first doped region 201, the second doped region 202 and the third doped region 203.

Specifically, when an ESD event occurs, a large voltage spike is applied between the first port and the second port. When the first port is coupled to a high potential and the second port is coupled to the low potential, the first diode 204 comes into a forward conducting state, and the second diode 205 comes into a reverse blocking state. The equivalent circuit of the electrostatic discharge protection device is shown in FIG. 3A. In this case, in the bipolar transistor formed by the first doped region 201, the second doped region 202 and the third doped region 203, the second doped region 202 constitutes an emitter, and the third doped region 203 constitutes a collector and the first doped region 201 constitutes a base. The bipolar transistor is reverse-biased, providing a discharge path of electrostatic discharge current in a forward direction. When the first port is coupled to the low potential and the second port is coupled to the high potential, the first diode 204 comes into a reverse blocking state and the second diode 205 comes into a forward conducting state. The equivalent circuit of the electrostatic discharge protection device is shown in FIG. 3B. In this case, in the bipolar transistor formed by the first doped region 201, the second doped region 202 and the third doped region 203, the second doped region 202 constitutes a collector, and the third doped region 203 constitutes an emitter and the first doped region 201 constitutes a base. The bipolar transistor is reverse biased, thereby providing a discharge path of electrostatic discharge current in a reverse direction. In summary, whether the first port is coupled to the high potential while the second port is coupled to the low potential, or the first port is coupled to the low potential while the second port is coupled to the high potential, a reverse-biased structure of the bipolar transistor formed by the first doped region 201, the second doped region 202, and the third doped region 203 can be achieved, thereby ensuring the bidirectional electrostatic discharge protection capability of the bidirectional electrostatic discharge protection device under different voltages. The bipolar transistor or the group of bipolar transistors can always provide bidirectional electrostatic discharge protection regardless of the changes in the value or direction of the voltage, thereby realizing the bidirectional electrostatic discharge protection of the bidirectional electrostatic discharge protection device provided by the present disclosure. The flexible structure effectively reduces the device area occupied by the bidirectional electrostatic discharge protection device. Meanwhile, the introduced on-resistance is also reduced to further improve the capability of electrostatic discharge protection.

In other embodiments, the bidirectional electrostatic discharge protection device is disposed between an input/output (I/O) terminal and a ground (GND) terminal of the protected device. The I/O terminal is the first port, and the GND terminal is the second port.

In other embodiments, the bidirectional electrostatic discharge protection device is disposed between an input/output (I/O) terminal and a ground (GND) terminal of the protected device. The I/O terminal is the second port, and the GND terminal is the first port.

The bidirectional electrostatic discharge protection device provided by the present disclosure has advantages of saving layout area, a low trigger voltage required, good protecting performance, a flexible structure, and providing protection under different voltages.

This disclosure has been described through the above embodiments, but it should be understood that the above embodiments are only for the purpose of illustration and description, and are not intended to limit the disclosure to the scope of the described embodiments. In addition, those skilled in the art can understand that the present disclosure is not limited to the above-mentioned embodiments. According to the teachings of the present disclosure, more variations and modifications can be made. These variations and modifications all fall within the scope of protection claimed in this disclosure. The scope of protection of this disclosure is defined by the appended claims and their equivalents.

1. A bidirectional electrostatic discharge protection device, comprising:
a first doped region with a first conductivity type;
a second doped region with a second conductivity type;
a third doped region with the second conductivity type, wherein the first doped region has a ring structure outside the second doped region and the third doped region;
a first diode having a cathode coupled to the first doped region, and an anode coupled to a first port together with the second doped region; and
a second diode having a cathode coupled to the first doped region, and an anode coupled to a second port together with the third doped region.

2. The bidirectional electrostatic discharge protection device according to claim 1, wherein the first doped region, the second doped region and the third doped region jointly form a bipolar transistor.

3. The bidirectional electrostatic discharge protection device according to claim 1, wherein the first doped region, the second doped region and the third doped region jointly form two or more bipolar transistors coupled in parallel.

4. The bidirectional electrostatic discharge protection device according to claim 1, wherein the second doped regions and the third doped regions are alternately arranged inside the first doped region.

5. The bidirectional electrostatic discharge protection device according to claim 4, wherein the second doped region and the third doped region are both elongated.

6. The bidirectional electrostatic discharge protection device according to claim 1, wherein the first doped region is heavily doped.

7. The bidirectional electrostatic discharge protection device according to claim 1, wherein the second doped region and the third doped region are heavily doped.

8. The bidirectional electrostatic discharge protection device according to claim 2, wherein, when the first port is coupled to a high potential and the second port is coupled to a low potential, the first diode is turned on while the second diode is turned off; and when the first port is coupled to the low potential and the second port is coupled to the high potential, the first diode is turned off while the second diode is turned on, so that static electricity is released with bidirectional electrostatic discharge protection by controlling the bipolar transistor.

9. The bidirectional electrostatic discharge protection device according to claim 1, wherein the first port is an I/O terminal and the second port is a ground terminal.

10. The bidirectional electrostatic discharge protection device according to claim 1, wherein the first port is a ground terminal and the second port is an I/O terminal.

11. The bidirectional electrostatic discharge protection device according to claim 1, wherein the first diode, the second diode, and the bipolar transistor formed by the first doped region, the second doped region and the third doped region are disposed in different well regions from one another.

12. The bidirectional electrostatic discharge protection device according to claim 1, wherein the first conductivity type is N-type and the second conductivity type is P-type.

13. The bidirectional electrostatic discharge protection device according to claim 1, wherein the first conductivity type is P-type and the second conductivity type is N-type.

14. The bidirectional electrostatic discharge protection device according to claim 3, wherein, when the first port is coupled to a high potential and the second port is coupled to a low potential, the first diode is turned on while the second diode is turned off; and when the first port is coupled to the low potential and the second port is coupled to the high potential, the first diode is turned off while the second diode is turned on, so that static electricity is released with bidirectional electrostatic discharge protection by controlling the bipolar transistor.
